(19) United States
(12) Patent Application Publication
(10) Pub. No.: US 2013/0207147 A1
(43) Pub. Date: Aug. 15, 2013

(54) UV LIGHT EMITTING DIODE AND METHOD OF MANUFACTURING THE SAME

(71) Applicants: Ki Bum Nam, Ansan-si (KR); Duck Hwan OH, Ansan-si (KR); Won Cheol Seo, Ansan-si (KR)

(72) Inventors: Ki Bum Nam, Ansan-si (KR); Duck Hwan OH, Ansan-si (KR); Won Cheol Seo, Ansan-si (KR)

(73) Assignee: SEOUL OPTO DEVICE CO., LTD., Ansan-si (KR)

(21) Appl. No.: 13/816,140

(22) PCT Filed: Jan. 18, 2011
(86) PCT No.: PCT/KR2011/000364

§ 371 Date: Feb. 21, 2013

(30) Foreign Application Priority Data
Aug. 11, 2010 (KR) 10-2010-0077213

(51) Int. Cl. H01L 33/10

(52) U.S. Cl. CPC H01L 33/10
USPC 257/98; 438/29

(57) ABSTRACT

The present disclosure provides a UV light emitting diode and a method of manufacturing the same. The UV light emitting diode includes a first conductive type semiconductor layer, an active layer, and a second conductive type semiconductor layer sequentially formed on a substrate, an electrode formed on the second conductive type semiconductor layer, and an opening formed by removing at least portions of the first conductive type semiconductor layer, the active layer, the second conductive type semiconductor layer, the reflective structure and the transparent electrode to expose a portion of the first conductive type semiconductor layer therethrough. In the UV light emitting diode, UV light is emitted from the active layer, passes through the opening, and then travels outside.

### CROSS-REFERENCE TO RELATED APPLICATIONS

This application is the National Stage Entry of International Application No. PCT/KR2011/000364, filed on Jan. 18, 2011, and claims priority from and the benefit of Korean Patent Application No. 10-2010-0077213, filed on Aug. 11, 2010, which are incorporated herein by reference as if fully set forth herein.

### BACKGROUND

1. Field

The present disclosure relates to an ultraviolet light emitting diode and a method of manufacturing the same. More particularly, the present disclosure relates to a UV light emitting diode that allows UV light generated in an active layer to be emitted through patterned portions formed by etching semiconductor layers, and a method of manufacturing the same.

2. Discussion of the Background

In recent years, high brightness white light emitting diodes using nitride semiconductors have attracted much attention as devices for illumination and are believed to hold considerable economic potential. There are three general methods for realizing such high brightness white light emitting diodes.

First, a white light emitting diode may be realized by combining three light emitting diodes of different colors, that is, a red light emitting diode, a green light emitting diode, and a blue light emitting diode. To manufacture a single high brightness white light emitting diode using this method, luminescence characteristics of these three light emitting diodes, such as temperature or device life, must be individually controlled, thereby making it difficult to realize a white light source.

Second, a white light emitting diode may be realized through excitation of yellow phosphors using a blue light emitting diode as a light source. The white light emitting diode manufactured by this method exhibits good luminescence efficiency. However, since the color rendering index (CRI) of the white light emitting diode manufactured by this method is low and varies according to current density, it is difficult to realize a high brightness white light emitting diode which can emit white light with a spectrum approaching that of sunlight.

Lastly, a white light emitting diode may be realized through excitation of three primary color phosphors using a UV light emitting diode as a light source. This method provides good luminescence efficiency and a high color rendering index, thereby making it possible to realize a high brightness white light emitting diode which can emit white light having a spectrum close to that of sunlight. In this method, however, an increase in efficiency of the UV light emitting diode is a very important issue.

Technologies relating to the UV light emitting diode are disclosed in Korean Patent No. 0608929 (Method of fabricating III-V nitride compound semiconductor ultraviolet light-emitting device, registered on Jul. 27, 2006) and Korean Patent No. 0709058 (Ultraviolet light-emitting device, registered on Apr. 12, 2007).

Two approaches have been used to improve efficiency of a light emitting diode. The first approach is an increase of internal quantum efficiency through control of crystal quality and epitaxial layer structure. The second approach is an increase of light extraction efficiency by taking into account the fact that large amounts of light generated in the light emitting diode is lost in the course of being emitted to the outside.

### SUMMARY

The present disclosure provides a UV light emitting diode that exhibits excellent optical efficiency in the UV band, and a method of manufacturing the same.

In accordance with one aspect of the present disclosure, a UV light emitting diode includes: a first conductive type semiconductor layer, an active layer, and a second conductive type semiconductor layer sequentially formed on a substrate; an electrode formed on the second conductive type semiconductor layer; and an opening formed by removing at least portions of the first conductive type semiconductor layer, the active layer, the second conductive type semiconductor layer and the electrode to expose a portion of the first conductive type semiconductor layer therethrough, wherein UV light is emitted to the outside from the active layer through the opening.

The electrode may comprise a material reflecting UV light.

The electrode may comprise a transparent electrode formed on the second conductive type semiconductor layer.

The transparent electrode may comprise at least one of Ni/Au, ITO, ZnO, SnO, NiO, and GaO.

The electrode may further comprise a reflective structure formed on the transparent electrode.

The electrode may further comprise a reflective structure formed between the transparent electrode and the second conductive type semiconductor layer.

The reflective structure may comprise aluminum (Al).

The active layer may comprise a compound semiconductor that enables emission of UV light having a peak wavelength in the range of 1 nm˜400 nm.

The active layer may have a compound semiconductor composition that enables emission of UV light having a peak wavelength in the range of 200 nm˜350 nm.

The opening may be formed in an array pattern of islands, in a plural-line pattern, or in a mesh pattern.

The UV light emitting diode may further include a reflective structure formed on a bottom surface of the opening.

The reflective structure formed on the bottom surface of the opening may be a distributed Bragg reflector.

In accordance with another aspect of the present disclosure, a method of manufacturing a UV light emitting diode includes: forming semiconductor layers on a substrate, the semiconductor layers including a first conductive type semiconductor layer, an active layer and a second conductive type semiconductor layer; forming an electrode on the second conductive type semiconductor layer; and forming an opening through which a portion of the first conductive type semiconductor layer is exposed, by removing at least portions of the first conductive type semiconductor layer, the active layer, the second conductive type semiconductor layer, and the electrode, wherein UV light is emitted to the outside from the active layer through the opening.

The electrode may comprise a material reflecting UV light.

The electrode may comprise a transparent electrode formed on the second conductive type semiconductor layer.

The transparent electrode may comprise at least one of Ni/Au, ITO, ZnO, SnO, NiO, and GaO.

The electrode may further comprise a reflective structure formed on the transparent electrode.

The electrode may further comprise a reflective structure formed between the transparent electrode and the second conductive type semiconductor layer.

The reflective structure may comprise aluminum (Al).

The method may further include forming a reflective structure on a bottom surface of the opening.

The reflective structure formed on the bottom surface of the opening may be a distributed Bragg reflector.

According to one embodiment, in a UV light emitting diode emitting light in the UV band, a first conductive type semiconductor layer, an active layer and a second conductive type semiconductor layer are partially removed by etching, so that light in the UV band generated by the active layer is emitted through openings formed by partially removing the first conductive type semiconductor layer, the active layer, the second conductive type semiconductor layer and the electrode, thereby reducing optical loss of UV light generated by the active layer, which is owing to the second conductive type semiconductor.

### BRIEF DESCRIPTION OF THE DRAWINGS

FIG. 1 is a side-sectional view of a UV light emitting diode according to one exemplary embodiment of the present disclosure;

FIG. 2 is a side-sectional view of a UV light emitting diode according to other exemplary embodiment of the present disclosure;

FIG. 3 is a side-sectional view of a UV light emitting diode according to another exemplary embodiment of the present disclosure; and

FIGS. 4 to 6 are side-sectional views of a method of manufacturing a UV light emitting diode according to one exemplary embodiment of the present disclosure.

### DETAILED DESCRIPTION OF THE ILLUSTRATED EMBODIMENTS

Exemplary embodiments of the present disclosure will be described in detail with reference to the accompanying drawings. The following embodiments are given by way of illustration to provide a thorough understanding of the invention to those skilled in the art. Hence, it should be understood that other embodiments will be evident based on the present disclosure, and that system, process or mechanical changes may be made without departing from the scope of the present disclosure. Likewise, it should be noted that the drawings are not to precise scale and some of the dimensions, such as width, length, thickness, and the like, are exaggerated for clarity of description in the drawings. Like elements are denoted by like reference numerals throughout the specification and drawings.

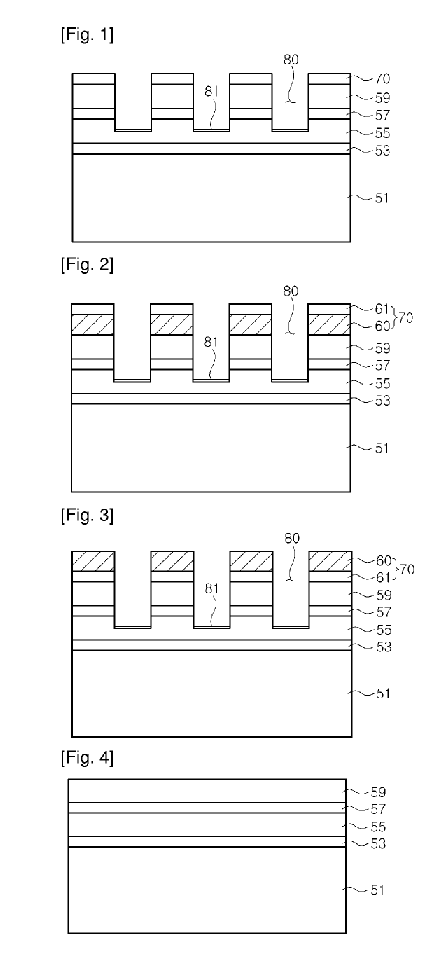

FIG. 1 is a side-sectional view of a UV light emitting diode according to one exemplary embodiment of the present disclosure.

Referring to FIG. 1, the UV light emitting diode according to the embodiment includes, on a substrate 51, compound semiconductor layers including a first conductive type semiconductor layer 55, an active layer 57, a second conductive type semiconductor layer 59, and a electrode 70.

The substrate 51 refers to a wafer for fabricating a nitride-based light emitting device. The substrate 51 may be formed using, but is not limited to, sapphire (Al₂O₃) or silicon carbide (SiC). The substrate may be a heterogeneous substrate such as silicon (Si), gallium arsenide (GaAs) or spinel, or a homogeneous substrate such as GaN, suitable for growth of nitride semiconductor layers thereon.

The first conductive type semiconductor layer 55 may be an n-type nitride semiconductor layer. Generally, the first conductive type semiconductor layer 55 may be formed of GaN, but is not limited thereto. Alternatively, the first conductive type semiconductor layer 55 may be an (Al, In, Ga)N-based binary to quaternary nitride semiconductor. Further, the first conductive type semiconductor layer 55 may be a single layer or multiple layers and include a super lattice layer.

The active layer 57 has a compound semiconductor composition that enables emission of UV light having a peak wavelength in the range of 1 nm˜400 nm. In one embodiment, the active layer 57 may have a compound semiconductor composition that enables emission of UV light having a peak wavelength in the range of 200 nm˜350 nm. The active layer 57 may have a single quantum well structure or a multi-quantum well structure. The active layer 57 is composed of a compound semiconductor layer having a composition of Ga_{1-x-y}InₓAl_{y}N (0≦x, y≦1, x+y≦1). In this case, the composition of the active layer 57 may be changed to adjust the peak wavelength.

The second conductive type semiconductor layer 59 may be a p-type nitride semiconductor layer. Generally, the second conductive type semiconductor layer 59 may be formed of GaN, but is not limited thereto. Alternatively, the second conductive type semiconductor layer 59 may be an (Al, In, Ga)N-based binary to quaternary nitride semiconductor. Further, the second conductive type semiconductor layer 59 may be formed using Mg as a dopant.

An electrode 70 is located on the second conductive type semiconductor layer 59.

The electrode 70 may comprise a material reflecting the light in UV band generated in the active layer 57. The electrode 70 may comprise aluminum (Al), for example. The electrode 70 may be a transparent electrode 70. That is, the electrode 70 is located on the reflective structure 60 and is formed of a transparent metal layer such as Ni/Au or a conductive transparent layer such as ITO, ZnO, SnO, NiO and GaO. In particular, GaO exhibits excellent transmittance in the UV band. The electrode 70 may be composed of a single layer or multiple layers.

The openings 80 are formed by partially etching the first conductive type semiconductor layer 55, the active layer 57, and the second conductive type semiconductor layer 59. According to this embodiment, UV light generated in the active layer 57 is emitted to the outside through the openings 80, which are formed by partially removing the first conductive type semiconductor layer 55, the active layer 57, and the second conductive type semiconductor layer 59.

A reflective structure 81 is formed on a bottom surface of the openings 80. Thus, when UV light generated in the active layer 57 is directed towards the bottom surface of the openings 80, the UV light may be reflected by the reflective structure 81 on the bottom surface of the opening 80 and then emitted upward. The reflective structure 81 may comprise at least one selected from Al, Si, Ti, Ta, Nb, In and Sn. Further, the reflective structure 81 may be formed by alternately stacking at least two layers selected from SiₓO_{y}N_{z}, TiₓO_{y}, TaₓO_{y} and NbₓO_{y}, and the reflective structure 81 may be a distributed Bragg reflector (DBR). The distributed Bragg reflector (DBR) may maximize reflectivity with respect to light in a specific wavelength range by regulating optical thicknesses of a high refractive index layer and a low refractive index layer alternately stacked on top of each other. Accordingly, it is possible to form the reflective structure 81 exhibiting high reflectivity with respect to, for example, UV light, by forming a distributed Bragg reflector that exhibits optimized reflectivity according to the wavelength of light generated in the active layer 57.

Meanwhile, the electrode 70 may comprise a reflective structure 60 formed on the second conductive type semiconductor layer 59 and a transparent electrode 61 formed on the reflective structure 60 as shown FIG. 2.

The reflective structure 60 may be composed of aluminum (Al). Al exhibits high reflectivity in the UV band, that is, 1 nm˜400 nm. Conversely, Ag or Au exhibits a remarkably low reflectivity in the UV band. Additionally, the reflective structure 60 may be composed of palladium (Pd), rhodium (Rh) or a metallic material comprising at least one of these elements. The reflective structure 60 reflects UV light generated in the active layer 57. Thus, the UV light reflected by the reflective structure 60 may be emitted to the outside through openings 80.

The transparent electrode 61 is located on the reflective structure 60 and is formed of a transparent metal layer such as Ni/Au or a conductive transparent layer such as ITO, ZnO, SnO, NiO and GaO. In particular, GaO exhibits excellent transmittance in the UV band. The transparent electrode 61 may be composed of a single layer or multiple layers. In addition to, the transparent electrode 61 is formed on the reflective structure to prevent an oxidation of the reflective structure 60, so that it can protect the reflective structure 60. And transparent electrode 61 can enhance current spreading. Meanwhile, the electrode 70 may comprise a transparent electrode 61 formed on the second conductive type semiconductor layer 59 and a reflective structure 60 formed on the a transparent electrode 61 as shown FIG. 3.

The transparent electrode 61 is located on the second conductive type semiconductor layer 59 and is formed of a transparent metal layer such as Ni/Au or a conductive transparent layer such as ITO, ZnO, SnO, NiO and GaO. In particular, GaO exhibits excellent transmittance in the UV band. The transparent electrode 61 may be composed of a single layer or multiple layers. In addition to, the transparent electrode 61 is formed between the reflective structure 60 and the second conductive semiconductor 29 to enhance ohmic characteristic with the second conductive semiconductor, and enhance current spreading.

The reflective structure 60 is formed on the transparent electrode 61 and is composed of aluminum (Al). Al exhibits high reflectivity in the UV band, that is, 1 nm˜400 nm. Conversely, Ag or Au exhibits a remarkably low reflectivity in the UV band. Additionally, the reflective structure 60 may be composed of palladium (Pd), rhodium (Rh) or a metallic material comprising at least one of these elements. The reflective structure 60 reflects UV light generated in the active layer 57. Thus, the UV light reflected by the reflective structure 60 may be emitted to the outside through openings 80.

FIGS. 4 to 6 are side-sectional views of a method of manufacturing a UV light emitting diode according to one exemplary embodiment as shown FIG. 1.

Referring to FIG. 4, compound semiconductor layers are formed on a substrate 51. The substrate 51 may be a sapphire substrate, but is not limited thereto. For example, the substrate 51 may be selected from other heterogeneous substrates. Here, the compound semiconductor layers include a first conductive type semiconductor layer 55, an active layer 57, and a second conductive type semiconductor layer 59. The compound semiconductor layers are III-N group compound semiconductor layers and may be grown by a process such as metal organic chemical vapor deposition (MOCVD), molecular beam epitaxy (MBE) or the like. The terms first and second conductive types mean an N-type and a P-type or vice versa, respectively.

Meanwhile, a buffer layer 53 may be formed before forming the compound semiconductor layers. The buffer layer 53 is adopted to relieve lattice mismatch between the substrate 51 and the compound semiconductor layers. Generally, the buffer layer may be a GaN-based material layer.

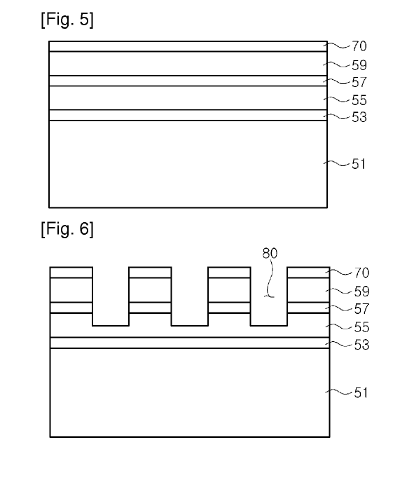

Referring to FIG. 5, a electrode 70 is formed on the second conductive type semiconductor layer 59 by deposition. The electrode 70 may be a transparent electrode , that is a transparent metal layer such as Ni/Au or a conductive transparent layer such as ITO, ZnO, SnO, NiO and GaO. In particular, GaO exhibits excellent transmittance in the UV wavelength band.

Referring to FIG. 6, after depositing the electrode 70, a pattern of openings 80 is formed by partially etching the electrode 70, the second conductive type semiconductor layer 59, the active layer 57, and the first conductive type semiconductor layer 55 via photolithography such that the first conductive type semiconductor layer 55 is partially exposed through the openings 80. In this case, the openings 80 may be formed in an array pattern of islands, in a plural-line pattern, or in a mesh pattern. Here, the ratio of the area occupied by the openings 80 formed by etching to the area which is not subjected to etching may be suitably adjusted in consideration of light extraction efficiency.

After forming the openings 80 by etching the electrode 70, the second conductive type semiconductor layer 59, the active layer 57, and the first conductive type semiconductor layer 55, a reflective structure 81 is formed on a bottom surface of the openings 80 by deposition, thereby providing a UV light emitting diode as shown in FIG. 1. Next, a lower electrode (not shown) is formed on an exposed portion of the first conductive type semiconductor layer 55. The reflective structure 81 may comprise at least one element selected from Al, Si, Ti, Ta, Nb, In, and Sn. Further, the reflective structure 81 may be formed by alternately stacking at least two layers selected from SiₓO_{y}N_{z}, TiₓO_{y}, TaₓO_{y} and NbₓO_{y} and the reflective structure 81 may be a distributed Bragg reflector (DBR). The distributed Bragg reflector (DBR) may maximize reflectivity with respect to light in a specific wavelength range by regulating optical thicknesses of a high refractive index layer and a low refractive index layer alternately stacked on top of each other. Accordingly, it is possible to form the reflective structure 81 exhibiting high reflectivity with respect to, for example, UV light, by forming a distributed Bragg reflector that exhibits optimized reflectivity according to the wavelength of light generated in the active layer 57.

Although some embodiments have been described in the present disclosure, it should be understood by those skilled in the art that these embodiments are given by way of illustration only, and that various modifications, variations, and alterations can be made without departing from the spirit and scope of the present disclosure. The scope of the present disclosure should be limited only by the accompanying claims and equivalents thereof.

1. An ultraviolet (UV) light emitting diode comprising:
a first type semiconductor layer, an active layer, and a second type semiconductor layer sequentially formed on a substrate;
an electrode arranged on the second type semiconductor layer; and
an opening formed in the first type semiconductor layer, the active layer, the second type semiconductor layer, and the electrode, so as to expose a portion of the first type semiconductor layer, and
wherein the active layer is configured to emit UV light through the opening, to the outside of the light-emitting diode.

2. The UV light emitting diode of claim 1, wherein the electrode is configured to reflect UV light.

3. The UV light emitting diode of claim 1, wherein the electrode comprises a transparent electrode arranged on the second type semiconductor layer.

4. The UV light emitting diode of claim 3, wherein the transparent electrode comprises at least one of Ni/Au, indium tin oxide (IT), ZnO, SnO, NiO, and GaO.

5. The UV light emitting diode of claim 3, wherein the electrode further comprises a reflective structure arranged on the transparent electrode.

6. The UV light emitting diode of claim 3, wherein the electrode further comprises a reflective structure disposed between the transparent electrode and the second type semiconductor layer.

7. The UV light emitting diode of claim 5, wherein the reflective structure comprises aluminum (Al).

8. The UV light emitting diode of claim 1, wherein the active layer is configured to emit UV light having a peak wavelength in the range of 1 nm to 400 nm.

9. The UV light emitting diode of claim 8, wherein the active layer is configured to emit UV light having a peak wavelength in the range of 200 nm to 350 nm.

10. The UV light emitting diode of claim 1, further comprising a plurality of openings, wherein the openings are arranged in an island pattern, a plural-line pattern, or a mesh pattern.

11. The UV light emitting diode of claim 1, further comprising a reflective structure arranged on the first type semiconductor layer and in the opening.

12. The UV light emitting diode of claim 11, wherein the reflective structure comprises a distributed Bragg reflector.

13. A method of manufacturing an ultraviolet (UV) light emitting diode, the method comprising:
forming a first type semiconductor layer, an active layer, and a second type semiconductor layer on a substrate;
forming an electrode on the second type semiconductor layer; and
forming an opening through the first type semiconductor layer, the active layer, the second type semiconductor layer, and the electrode, so as to expose a portion of the first type semiconductor layer
wherein the active layer is configured to emit UV light through the opening, to the outside of the light-emitting diode.

14. The method of claim 13, wherein the electrode comprises a material configured to reflect UV light.

15. The method of claim 13, wherein the electrode comprises a transparent electrode formed on the second type semiconductor layer.

16. The method of claim 15, wherein the transparent electrode comprises at least one of Ni/Au, indium tin oxide (ITO), ZnO, SnO, NiO, and GaO.

17. The method of claim 15, wherein the electrode further comprises a reflective structure formed on the transparent electrode.

18. The method of claim 15, wherein the electrode further comprises a reflective structure disposed between the transparent electrode and the second type semiconductor layer.

19. The method of claim 13, further comprising forming a reflective structure on the first type semiconductor layer and in the opening.
